(19) United States
(12) Patent Application Publication
(10) Pub. No.: US 2023/0328923 A1
(43) Pub. Date: Oct. 12, 2023

(54) HEAT DISSIPATION DEVICE

(71) Applicants: MICRO-STAR INT'L CO., LTD., New Taipei City (TW); MSI COMPUTER (SHENZHEN) CO., LTD., Shenzhen City (CN)

(72) Inventors: Lin-Yu LEE, New Taipei City (TW); Shang-Chih YANG, New Taipei City (TW); Yung-Ching HUANG, New Taipei City (TW)

(73) Assignees: MICRO-STAR INT'L CO., LTD., New Taipei City (TW); MSI COMPUTER (SHENZHEN) CO., LTD., Shenzhen City (CN)

(21) Appl. No.: 17/840,198

(22) Filed: Jun. 14, 2022

(30) Foreign Application Priority Data
Apr. 8, 2022 (TW) 111113437

(51) Int. Cl. H05K 7/20

(52) U.S. Cl. CPC H05K 7/20263; H05K 7/20409; H05K 7/20272; H05K 7/20136

(57) ABSTRACT

A heat dissipation device is provided, including a main body, a plurality of fins, a plurality of flat tubes, a pump head, and a fan. The pump head and the fan are disposed on opposite sides of the main body. The main body has three tanks arranged along the long axis of the main body. The flat tubes communicate with the tanks. The fins are disposed on the flat tubes.

### CROSS REFERENCE TO RELATED APPLICATIONS

This application claims priority of Taiwan Patent Application No. 111113437, filed on Apr. 8, 2022, the entirety of which is incorporated by reference herein.

### BACKGROUND OF THE INVENTION

### Field of the Invention

The present invention relates to heat dissipation device, and, in particular, to a liquid cooler.

### Description of the Related Art

With the progress being made in computer technologies and the rapid development of the gaming industry, a variety of graphics cards capable of high computing speeds have been provided. As the Graphics Processing Unit (GPU) in a graphics card may generate a lot of heat during usage, fans and thermal fins are usually included, to aid in rapid heat dissipation. Designing a heat dissipation device that can efficiently cool the GPU of a graphics card has been a significant challenge to engineers.

### BRIEF SUMMARY OF THE INVENTION

An embodiment of the present invention provides a heat dissipation device for cooling a circuit module. The heat dissipation device includes a main body, a plurality of fins, a pump head, and a fan. The main body has a first tank, a second tank, a third tank, a plurality of first flat tubes, and a plurality of second flat tubes. The first, second, and third tanks are arranged along the long axis of the main body, the first flat tubes communicate with the first and second tanks, and the second flat tubes communicate with the second and third tanks. The fins are disposed on the first and second flat tubes. The pump head is communicated with the first tank and forcing a liquid to circulate between the pump head and the main body. The fan is disposed on the main body, wherein the fan and the pump head are located on opposite sides of the main body.

In some embodiments, the fins include a plurality of first fins, second fins, third fins, and fourth fins. Each of the first, second, third, and fourth fins has a meandering structure. The first and second fins are disposed between the first and second tanks, and the third and fourth fins are disposed between the second and third tanks, wherein the first and second fins have different pitch distances, and the third and fourth fins have different pitch distances.

In some embodiments, a high-temperature flow path area and a low-temperature flow path area are defined on the main body, the first and third fins are located in the high-temperature flow path area, and the second and fourth fins are located in the low-temperature flow path area.

In some embodiments, the pitch distance of the first fins is greater than the pitch distance of the second fins, and the pitch distance of the third fins is greater than the pitch distance of the fourth fins.

In some embodiments, the thickness of the third tank is greater than the thickness of the second tank in the vertical direction, and the thickness of the second tank is greater than the thickness of the first tank in the vertical direction, wherein the vertical direction is perpendicular to the long axis of the main body.

In some embodiments, the pump head is disposed between the first and second tanks.

In some embodiments, when viewed along the long axis of the main body, the pump head, the second tank, and the third tank partially overlap.

In some embodiments, the heat dissipation device further includes two fans, wherein a first recess is formed between the first and second tanks, a second recess is formed between the second and third tanks, and the fans are disposed in the first and second recesses.

In some embodiments, the heat dissipation device further includes a thermal block connected to the pump head and an IC element of the circuit module.

In some embodiments, the circuit module comprises a graphics card, and the IC element comprises a GPU.

### BRIEF DESCRIPTION OF THE DRAWINGS

The present invention can be more fully understood by reading the subsequent detailed description and examples with references made to the accompanying drawings, wherein:

FIG. 1 is an exploded diagram of a heat dissipation device K and a circuit module 40, in accordance with another embodiment of the invention.

FIG. 2 is another exploded diagram of the heat dissipation device K and the circuit module 40 in FIG. 1.

FIGS. 3 and 4 are perspective diagrams of the main body 10 in FIGS. 1 and 2.

FIG. 5 is a side view of the main body 10 in FIGS. 3 and 4.

FIG. 6 is a perspective diagram showing the main body 10, the pump head 20, and the thermal block P.

FIG. 7 is a perspective diagram of the heat dissipation device K and the circuit module 40 after assembly.

FIG. 8 is a bottom view of the main body 10 of the heat dissipation device K.

### DETAILED DESCRIPTION OF THE INVENTION

The making and using of the embodiments of the heat dissipation device are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

In the following detailed description of the preferred embodiments, reference is made to the accompanying drawings, and in which specific embodiments of which the invention may be practiced are shown by way of illustration. In this regard, directional terminology, such as “top,” “bottom,” “left,” “right,” “front,” “back,” etc., is used with reference to the orientation of the figures being described. The components of the present invention can be positioned in a number of different orientations. As such, the directional terminology is used for the purposes of illustration and is in no way limiting.

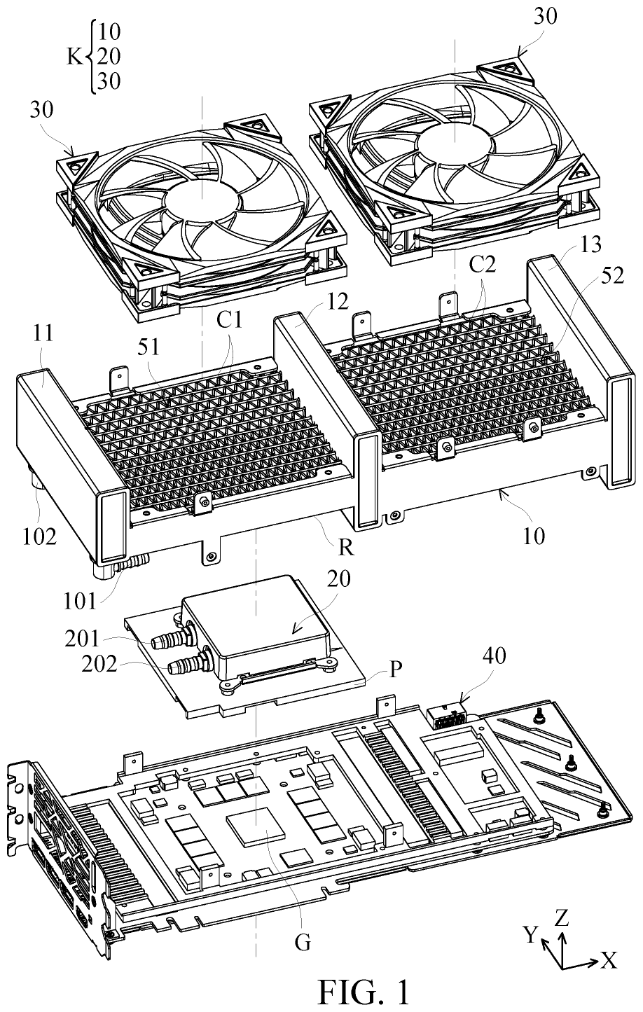

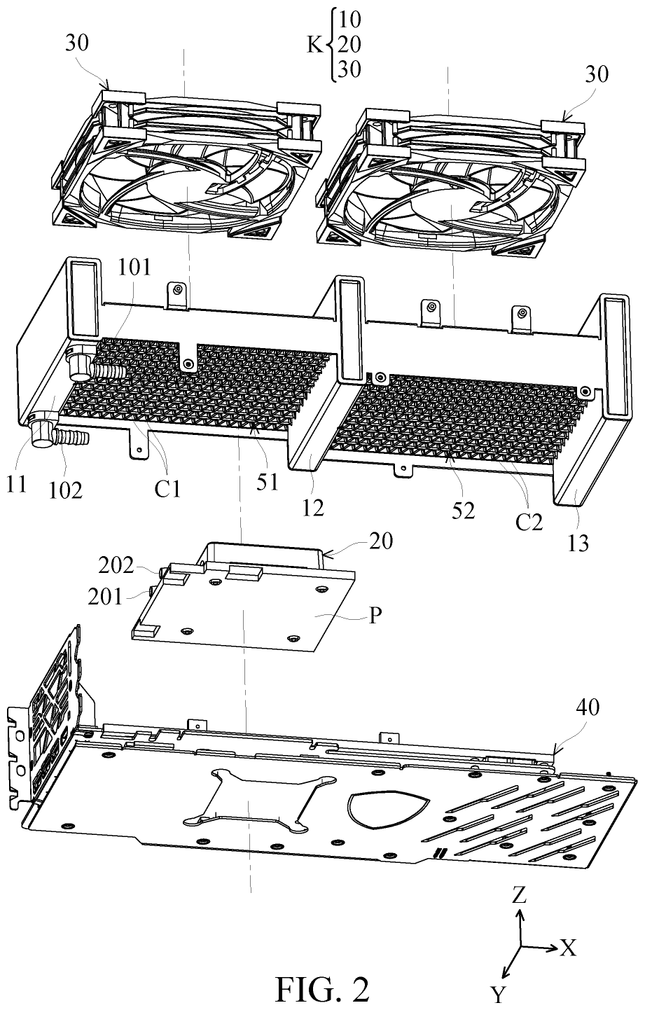

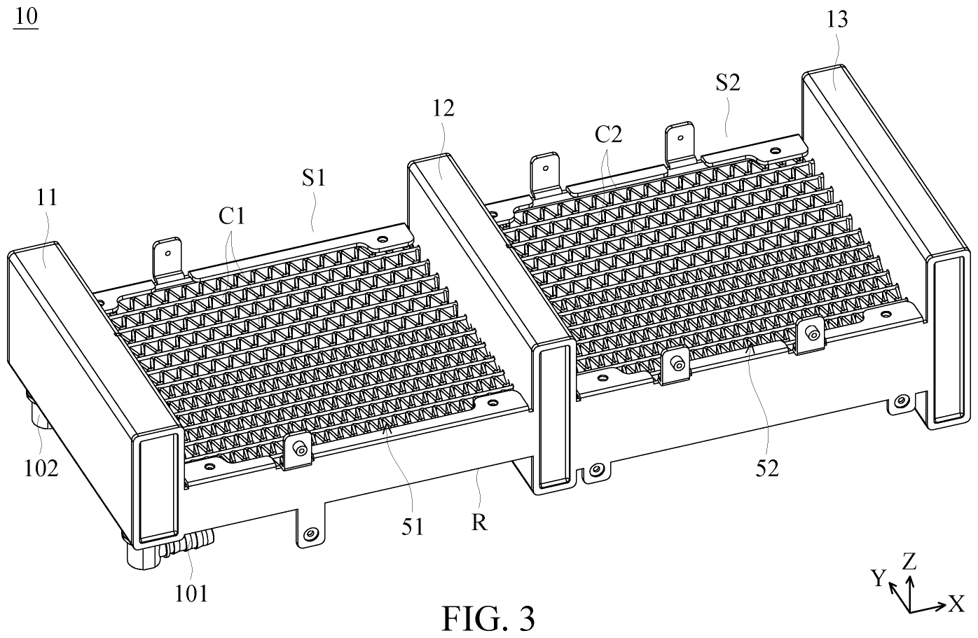

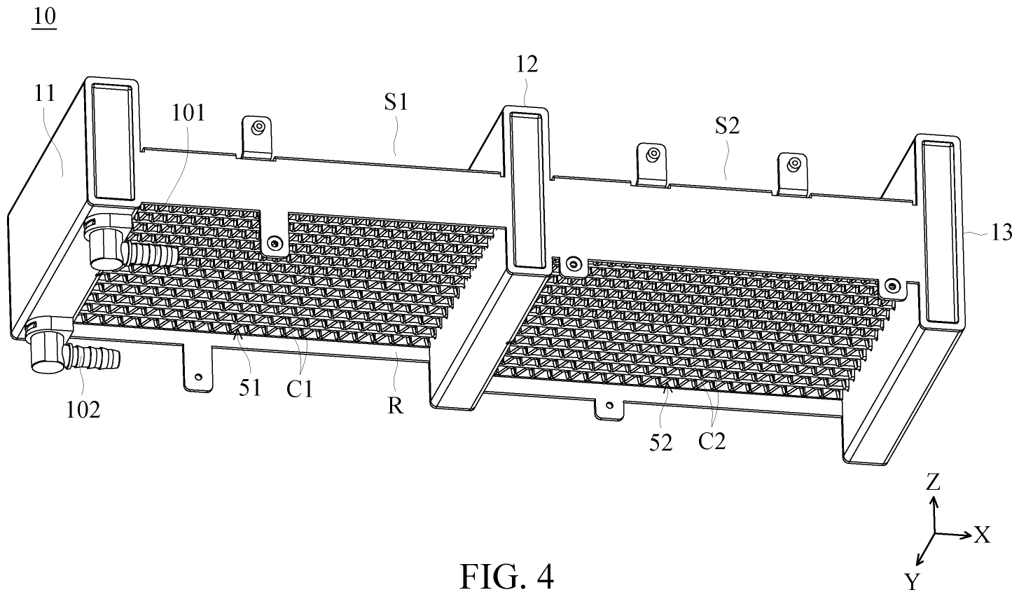

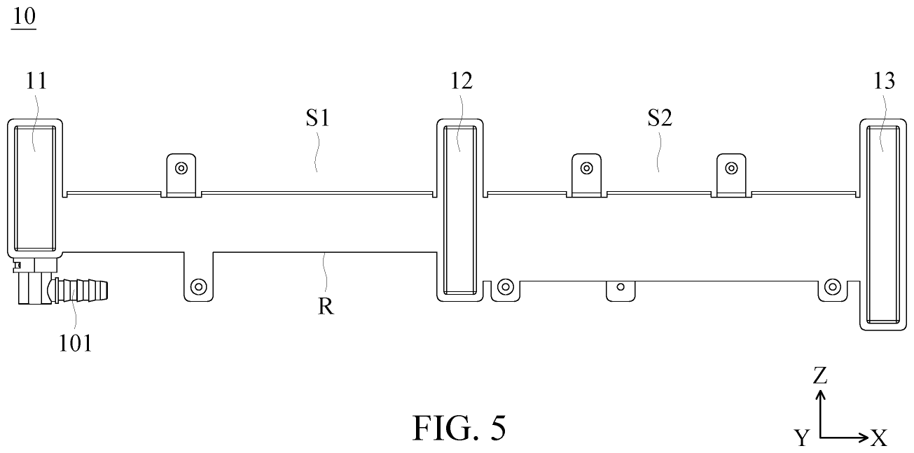

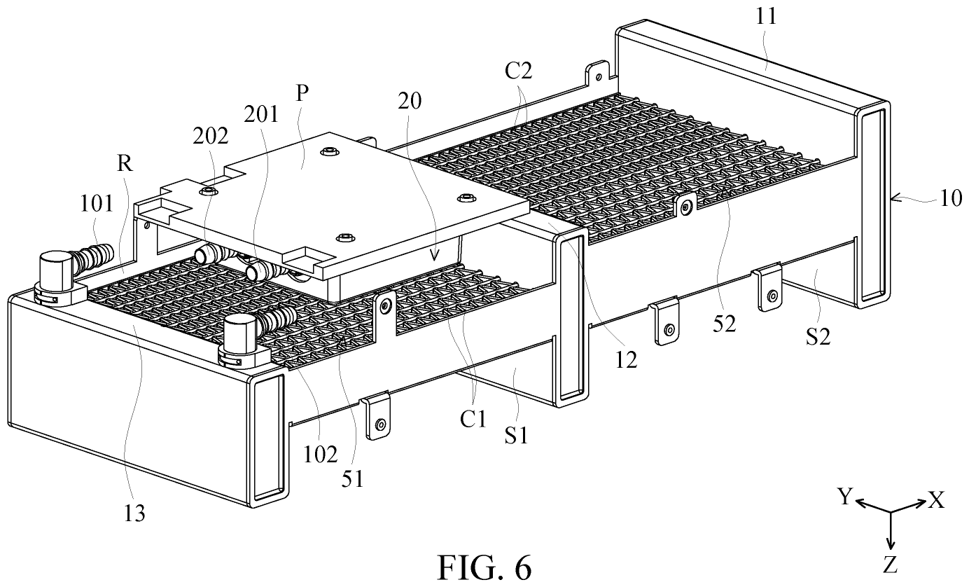

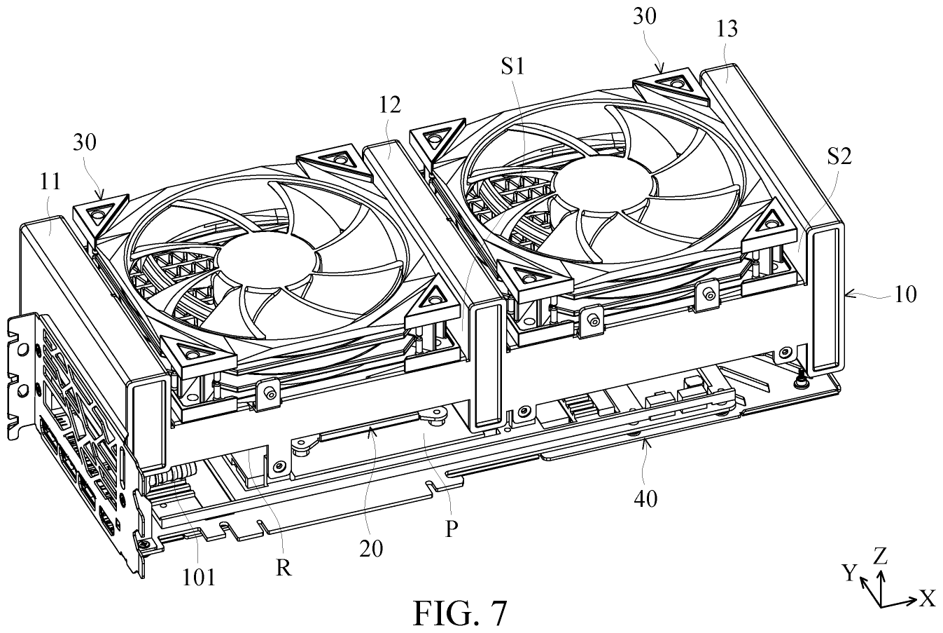

FIG. 1 is an exploded diagram of a heat dissipation device K and a circuit module 40, in accordance with another embodiment of the invention. FIG. 2 is another exploded diagram of the heat dissipation device K and the circuit module 40 in FIG. 1. FIGS. 3 and 4 are perspective diagrams of the main body 10 in FIGS. 1 and 2. FIG. 5 is a side view of the main body 10 in FIGS. 3 and 4. FIG. 6 is a perspective diagram showing the main body 10, the pump head 20, and the thermal block P. FIG. 7 is a perspective diagram of the heat dissipation device K and the circuit module 40 after assembly.

Referring to FIGS. 1 and 2, an embodiment of the heat dissipation device K may be a liquid cooler that is disposed on a circuit module 40 (e.g. a graphics card), and it can be used to cool an IC element G (e.g. GPU) on the surface of the circuit module 40.

The heat dissipation device K primarily comprises a hollow main body 10, a pump head 20, and at least a fan 30, wherein the fan 30 and the pump head 20 disposed on the upper and lower sides of the main body 10. In this embodiment, the main body 10 comprises a first tank 11, a second tank 12, a third tank 13, a plurality of first flat tubes C1, and a plurality of second flat tubes C2.

As shown in FIGS. 1 to 7, the first, second, and third tanks 11, 12, and 13 are arranged in a direction parallel to the long axis (X direction) of the main body 10. The first flat tubes C1 communicate with the first and second tanks 11 and 12, and the second flat tubes C2 communicate with the second and third tanks 12 and 13.

It should be noted that the liquid (e.g. water or other coolant) in the first tank 11 can be forced to flow and discharged via the outlet 101 by the pump head 20. In this embodiment, the liquid can flow through a conduit (not shown) and enter the pump head 20 via the inlet 201. Similarly, the liquid in the pump head 20 can be discharged via the outlet 202 to the main body 10. In this embodiment, the liquid can flow through a conduit (not shown) and enter the first tank 11 via the inlet 102.

Additionally, a thermal block P is disposed at the bottom of the pump head 20. Here, the thermal block P is connected to an IC element G of the circuit nodule 40 via thermal paste. Hence, heat generated by the IC element G can be transferred through the thermal block P to the pump head 20, and the liquid (e.g. water) in the pump head 20 can bring heat to the main body 10 for cooling the IC element G.

Still referring to FIGS. 1-7, a plurality of meandering fins 51 and 52 are disposed on the main body 10. The fins 51 and 52 may comprise metal, wherein the fins 51 are mounted between the flat tubes C1 by welding, and the fins 52 are also mounted between the flat tubes C2 by welding, thereby achieving high efficiency of heat transfer.

In this embodiment, the fins 51 are affixed to the flat tubes C1 between the first and second tanks 11 and 12, and the fins 52 are affixed to the flat tubes C2 between the second and third tanks 12 and 13, wherein both of the wave-shaped (or zig-zag) fins 51 and 52 have different pitch distances (densities).

It should be noted that after the liquid (e.g. water or other coolant) is heated and transferred from the pump head 20 to the main body 10, the liquid can flow from the first tank 11 through the first flat tubes C1 to the second tank 12, and then flow from the second tank 12 through the second flat tubes C2 to the third tank 13. When the liquid flows through the first and second flat tubes C1 and C2, heat can be rapidly dissipated to the air by the wind flow generated from the fans 30, thus facilitating high efficiency of cooling.

Furthermore, as shown in FIGS. 3-7, a first recess S1 is formed between the first and second tanks 11 and 12, and a second recess S2 is formed between the second and third tanks 12 and 13. The first and second recess S1 and S2 are provided for receiving the fans 30 and achieving rapid heat dissipation of the circuit module 40.

In FIG. 5, the thickness of the third tank 13 is greater than the thickness of the first and second tanks 11 and 12 in the vertical direction (Z direction). Here, the thickness of the second tank 12 is greater than the thickness of the first tank 11 in the vertical direction, wherein the vertical direction is perpendicular to the long axis (X direction) of the main body 10.

Additionally, the thickness of the fins 52 and the second flat tubes C2 is greater than the thickness of the fins 51 and the first flat tubes C1 in the vertical direction (Z direction). Here, an accommodating space R is formed below the fins 51 and the first flat tubes C1 for receiving the pump head 20. In FIG. 7, the pump head 20 is located between the main body 10 and the circuit nodule 40 after assembly. When viewed in a direction parallel to the long axis (X direction) of the main body 10, the pump head 20, the second tank 12, and the third tank 13 at least partially overlap.

In this embodiment, the accommodating space R is located between the first and second tanks 11 and 12 along the X axis.

As the heat dissipation device K has three tanks communicated with each other via the flat tubes, the volume of the liquid/coolant can increase to enhance the cooling efficiency. Specifically, air in the main body can be captured and retained in the tanks while the liquid/coolant cycling in the closed flow system, thereby facilitating high efficiency of heat exchange. Moreover, as the tanks have different thicknesses, efficient space utilization and miniaturization of the heat dissipation device K and the circuit module 40 can be also achieved.

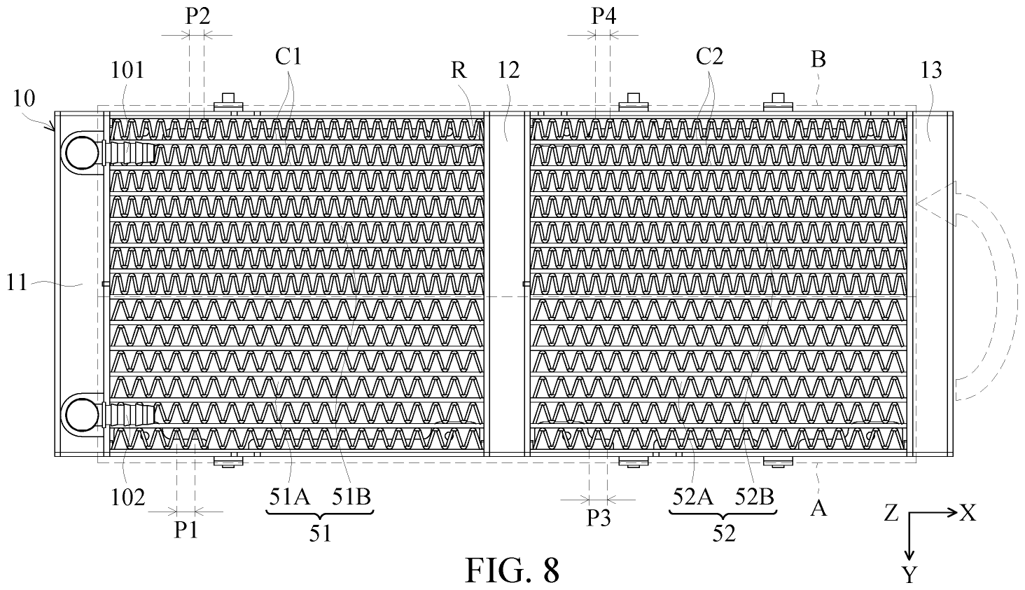

FIG. 8 is a bottom view of the main body 10 of the heat dissipation device K.

As shown in FIG. 8, a high-temperature flow path area A and a low-temperature flow path area B are defined on the main body 10. In this embodiment, after the liquid/coolant (e.g. water) is heated and flows from the pump head 20 through the inlet 102 to the first tank 11, it moves through the high-temperature flow path area A in the X direction (sequentially through the first flat tubes C1, the second tank 12, the second flat tubes C2 to the third tank 13). As the arrow indicates in FIG. 8, the liquid/coolant subsequently flows from the third tank 13 through the low-temperature flow path area B to the first tank 11 in the −X direction (sequentially through the second flat tubes C2, the second tank 12, the first flat tubes C1 to the first tank 11). Hence, the liquid/coolant in the main body 10 is cooled and can be discharged from the outlet 101 to the pump head 20 to complete the circulation loop.

It should be noted that the wave-shaped or zig-zag fins 51 between the first and second tanks 11 and 12 include a plurality of first fins MA and second fins MB that have different pitch distances (densities). Similarly, the wave-shaped or zig-zag fins 52 between the second and third tanks 12 and 13 include a plurality of third fins 52A and fourth fins 52B that have different pitch distances (densities).

In some embodiments, the first fins 51A may have a pitch distance P1 of about 3.2 mm, and the second fins 51B may have a pitch distance P2 of about 2.5 mm. Similarly, the third fins 52A may have a pitch distance P3 of about 3.2 mm, and the fourth fins 52B may have a pitch distance P4 of about 2.5 mm.

It should be noted that the pitch distances P1 and P3 of the first and third fins 51A and 52A in the high-temperature flow path area A are greater than the pitch distances P2 and P4 of the second and fourth fins 51B and 52B in the low-temperature flow path area B. With the different pitch distances of the fins 51 and 52 in the high-temperature and low-temperature flow path areas A and B, heat can be dissipated by the air flow generated from the fans 30 more rapidly and efficiently, thus facilitating high performance of cooling.

In some embodiments, both of the fins 51 and 52 may have more than three kinds of pitch distances, not limited to the embodiments of the invention.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it should be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A heat dissipation device for cooling a circuit module, comprising:
a main body, having a first tank, a second tank, a third tank, a plurality of first flat tubes, and a plurality of second flat tubes, wherein the first, second, and third tanks are arranged along a long axis of the main body, the first flat tubes communicate with the first and second tanks, and the second flat tubes communicate with the second and third tanks;
a plurality of fins, disposed on the first and second flat tubes;
a pump head, communicated with the first tank and forcing a liquid to circulate between the pump head and the main body; and
a fan, disposed on the main body, wherein the fan and the pump head are located on opposite sides of the main body.

2. The heat dissipation device as claimed in claim 1, wherein the fins include a plurality of first fins, second fins, third fins, and fourth fins, and each of the first, second, third, and fourth fins has a meandering structure, wherein the first and second fins are disposed between the first and second tanks, and the third and fourth fins are disposed between the second and third tanks, wherein the first and second fins have different pitch distances, and the third and fourth fins have different pitch distances.

3. The heat dissipation device as claimed in claim 2, wherein a high-temperature flow path area and a low-temperature flow path area are defined on the main body, the first and third fins are located in the high-temperature flow path area, and the second and fourth fins are located in the low-temperature flow path area.

4. The heat dissipation device as claimed in claim 3, wherein the pitch distance of the first fins is greater than the pitch distance of the second fins, and the pitch distance of the third fins is greater than the pitch distance of the fourth fins.

5. The heat dissipation device as claimed in claim 1, wherein the thickness of the third tank is greater than the thickness of the second tank in a vertical direction, and the thickness of the second tank is greater than the thickness of the first tank in the vertical direction, wherein the vertical direction is perpendicular to the long axis of the main body.

6. The heat dissipation device as claimed in claim 1, wherein the pump head is disposed between the first and second tanks.

7. The heat dissipation device as claimed in claim 1, wherein when viewed along the long axis of the main body, the pump head, the second tank, and the third tank partially overlap.

8. The heat dissipation device as claimed in claim 1, further comprising two fans, wherein a first recess is formed between the first and second tanks, a second recess is formed between the second and third tanks, and the fans are disposed in the first and second recesses.

9. The heat dissipation device as claimed in claim 1, further comprising a thermal block connected to the pump head and an IC element of the circuit module.

10. The heat dissipation device as claimed in claim 9, wherein the circuit module comprises a graphics card, and the IC element comprises a GPU.
